(19) United States
(12) Patent Application Publication
(10) Pub. No.: US 2012/0231609 A1
(43) Pub. Date: Sep. 13, 2012

(54) VAPOR-PHASE GROWING APPARATUS AND VAPOR-PHASE GROWING METHOD

(76) Inventor: Yuusuke SATO, Tokyo (JP)

(21) Appl. No.: 13/220,226

(22) Filed: Aug. 29, 2011

(30) Foreign Application Priority Data
Mar. 9, 2011 (JP) P2011-051549

(51) Int. Cl. H01L 21/20; C23C 16/22; C23C 16/44

(52) U.S. Cl. 438/478; 118/728; 257/E21.09

(57) ABSTRACT

According to one embodiment, a vapor-phase growing apparatus, includes: a reactor containing a gas introduction portion and a gas reaction portion continued from the gas introduction portion; a susceptor, of which a surface is exposed in an interior space of the gas reaction portion of the reactor, for disposing and fixing a substrate on the surface thereof; a plurality of gas inlet conduits which are arranged subsequently along a direction of height of the reactor in the gas introduction portion of the reactor; and a switching device, which is provided in an outside of the reactor, for switching gases to be supplied to the gas inlet conduits, respectively.

### CROSS-REFERENCE TO RELATED APPLICATION

This application is based upon and claims the benefit of priority from Japanese Patent Application No. 2011-051549 filed on Mar. 9, 2011, the entire contents of which are incorporated herein by reference.

### FIELD

Embodiments described herein relate generally to a vapor-phase growing apparatus and a vapor-phase growing method.

### BACKGROUND

Metal Organic Chemical Vapor deposition (MOCVD) is a one of typical vapor-phase growing methods and according to the MOCVD, a group-III metal organic (MO) precursor is gasified and supplied with a carrier gas and a group V gas onto a substrate so that the group-III MO precursor is thermally reacted with the group-V gas on the surface of the substrate to form a film thereon. Since the MOCVD can control the thickness and composition of the film and have excellent productivity, the MOCVD can be widely available as a film-forming technique in the manufacture of semiconductor devices.

An MOCVD apparatus to be employed in the MOCVD includes a reactor, a susceptor disposed in the reactor and gas conduits for flowing reaction gases onto the surface of a substrate disposed on the susceptor. In the MOCVD apparatus, the substrate is disposed on the susceptor and heated at a prescribed temperature while raw material gases such as MO gas and a subflow gas such as nitrogen gas are introduced onto the surface of the substrate through the respective gas conduits so as to conduct the intended thin film-forming process.

In the case that a plurality of films are stacked by the MOCVD to form a predetermined device, the films are subsequently formed by using the same MOCVD apparatus. Since the compositions of the films are different from one another, however, it may be required that one or more of the raw material gases to be introduced into the reactor through the respective gas conduits are varied remarkably in kind and flow rate per film.

Particularly, if the flow rates of the respective raw material gases to be introduced into the reactor through the gas conduits are varied remarkably, the unbalance of static pressure is likely to occur at the gas mixing portion of the reactor. In the case that an attention is paid to one of the gas conduits, for example, if the flow rate of the raw material to be supplied through the corresponding gas conduit is increased, the flow velocity of the raw material gas is also increased.

When the flow velocity of a gas is defined as “u”, the density of the gas is defined as “ρ”, the static pressure is defined as “p” and the total pressure is defined as “p0”, the following relation can be satisfied.

p=p0−ρu²/2 (1)

When the flow velocity of one of the raw material gases is increased, the static pressure around the corresponding gas flow is decreased so that another one or other ones of the raw material gases or the subflow gas is attracted to the corresponding gas flow by the difference in static pressure thereof and thus the vortex flow of the raw material gases and/or the subflow gas may be produced in the reactor. Therefore, the gas flows of the raw material gases and/or the subflow gas are disturbed so that the raw material gases and/or the subflow gas cannot be supplied uniformly onto the substrate, resulting in the ununiformity in thickness and composition and thus the conspicuous deterioration in reproducibility at the film-forming process.

Moreover, when the kind of gas is varied, the density of the corresponding gas is also varied. In this case, the static pressure may be changed and thus the gas flow may become unstable.

Furthermore, the raw material gases and/or the subflow gas are reached to the upper wall surface and the lower wall surface of the reactor originated from the aforementioned disturbances of the raw material gases and/or the subflow gas, so that given depositions may be formed at the upper wall surface and the lower wall surface. The depositions may be exfoliated during the use of reactor, that is, the MOCVD apparatus and thus adhered with and/or deposited on the film formed on the substrate, causing the deterioration in quality of the film.

In addition, in the case that the aforementioned vortex flow is produced at the gas mixing portion, the raw material gases may be mixed and reacted with one another to form particles. The depositions and the particles cause the loss of the raw material gases and deteriorate the productivity. Even more, the depositions may change the temperature of the reactor and the gas flow in the reactor, deteriorating the reproducibility of film-forming process.

In order to supply the raw material gases and the subflow gas onto the substrate uniformly, such an MOCVD apparatus as including a susceptor for disposing a substrate thereon and paths for introducing reaction gases onto the substrate is taught. The paths are configured as a lateral three-laminar flow type paths and elongated in parallel with the disposing surface of the susceptor. Then, the subflow gas is supplied from the furthest path relative to the substrate and the group III gas is supplied from the center path while the group III gas is also supplied from the nearest path relative to the substrate.

Even in the use of the aforementioned technique, however, it is difficult to suppress the disturbances of the gas flows of the raw material gases when the flow rate of one of the raw material gases is changed remarkably as described above and thus to supply the raw material gases onto the substrate uniformly. Therefore, the reproducibility at the film-forming process and the deterioration in quality of the film due to the exfoliation of the depositions formed on the inner wall surface of the reactor cannot be sufficiently suppressed.

### BRIEF DESCRIPTION OF THE DRAWINGS

FIG. 1 is a cross sectional view schematically showing the structure of a vapor-phase growing apparatus according to a first embodiment.

FIG. 2 is a schematic view showing the structure of a switching device in the vapor-phase growing apparatus in FIG. 1.

FIG. 3 is an explanatory view relating to a vapor-phase growing method according to the first embodiment.

FIG. 4 is an explanatory view relating to a vapor-phase growing method according to the first embodiment.

FIG. 5 is a cross sectional view schematically showing the structure of a vapor-phase growing apparatus according to a second embodiment.

### DETAILED DESCRIPTION

According to one embodiment, a vapor-phase growing apparatus, includes: a reactor containing a gas introduction portion and a gas reaction portion continued from the gas introduction portion; a susceptor, of which a surface is exposed in an interior space of the gas reaction portion of the reactor, for disposing and fixing a substrate on the surface thereof; a plurality of gas inlet conduits which are arranged subsequently along a direction of height of the reactor in the gas introduction portion of the reactor; and a switching device, which is provided in an outside of the reactor, for switching gases to be supplied to the gas inlet conduits, respectively.

### First Embodiment

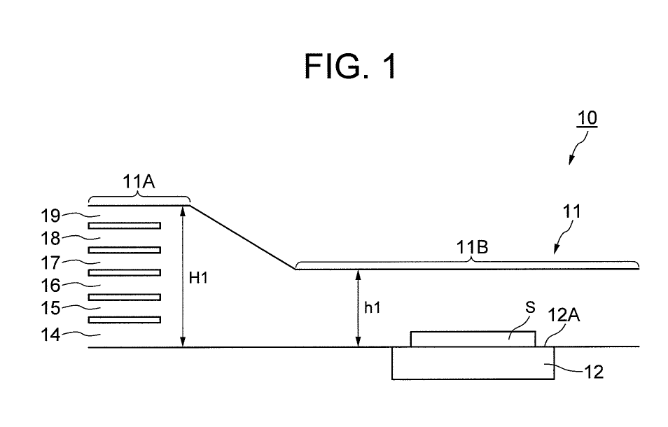

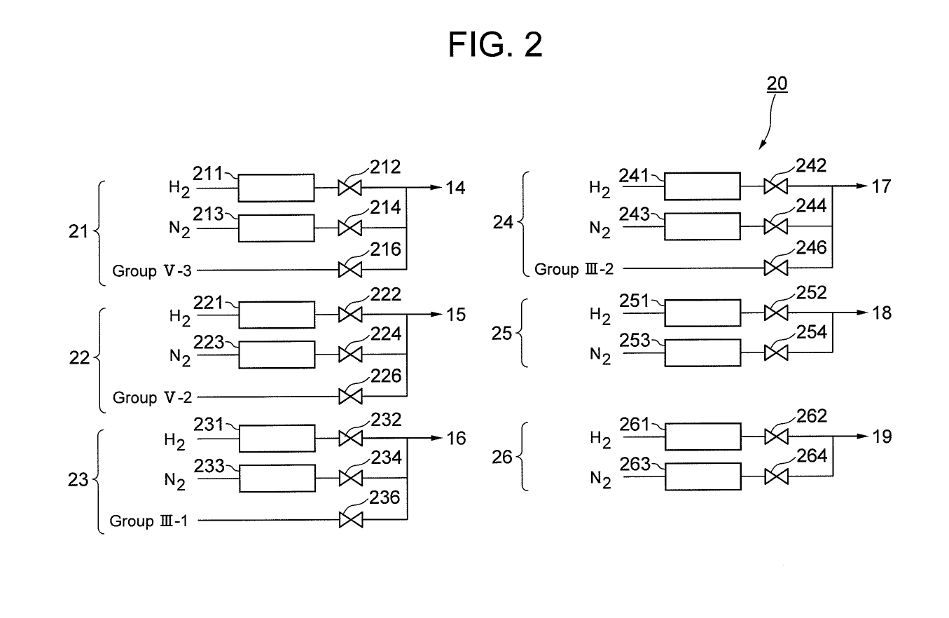

FIG. 1 is a cross sectional view schematically showing the structure of a vapor-phase growing apparatus according to a first embodiment, and FIG. 2 is a schematic view showing the structure of a switching device in the vapor-phase growing apparatus in FIG. 1.

As shown in FIG. 1, a vapor-phase growing apparatus 10 in this embodiment includes a reactor 11 containing a gas introduction portion 11A and a gas reaction portion 11B continued from the gas introducing portion 11A and a susceptor 12 of which the surface is exposed to the interior space of the gas reactive portion 11B.

As shown in FIG. 1, the reactor 11 is configured as a so-called lateral reactor because the gas introduction portion 11A and the gas reaction portion 11B are laterally continued from one another. The susceptor 12 is heated by a not shown heater so as to heat the substrate S to a predetermined temperature.

In the reactor 11, the height “H1” of the gas introduction portion 11A is set equal to the height “h1” of the gas reaction portion 11B, but desirably, the height “H1” of the gas introduction portion 11A is set larger than the height “h1” of the gas reaction portion 11B. If the height “H1” of the gas introduction portion 11A is set larger, the cross section of the flow path becomes larger and the flow velocity “u” becomes lower. As indicated in Equation (1), if the flow velocity “u” becomes lower, the difference in the static pressure “p” can be rendered smaller.

The ratio (H1/h1) of the height “H1” of the gas introduction portion 11A to the height “h1” of the gas reaction portion 11B is set within a range of 1 to 5. However, the concrete height “H1” and the concrete height “h1” are determined in view of the size of the substrate S, the flow rates of the gases to be used at the film-forming processes for the substrate S, the growing pressure and the like.

In the gas introduction portion 11A of the reactor 11, six gas inlet conduits are subsequently arranged along the direction of the height of the reactor 11. Here, reference numerals “14”, “15”, “16”, “17”, “18” and “19” are imparted to the six gas inlet conduits subsequently from the bottom thereof (hereinafter, the six gas inlet conduits are called as a first gas inlet conduit 14, a second gas inlet conduit 15, a third gas inlet conduit 16, a fourth gas inlet conduit 17, a fifth gas inlet conduit 18 and a sixth gas inlet conduit 19). The number of gas inlet conduit is not limited to six, but may be set to any number as occasion demands.

In the vapor-phase growing apparatus 10 in this embodiment, a switching device 20 for switching the gases to be supplied to the gas inlet conduits 14 to 19 is provided in the outside of the reactor 11.

As shown in FIG. 2, the switching device 20 has six switching elements 21 to 26 in accordance with the gas inlet conduits 14 to 19. Hereinafter, a “carrier gas” means a gas accompanied with each of the raw material gases and a “subflow gas” means a gas not accompanied with each of the raw material gases.

The first switching element 21 is an element for switching the gases to be supplied to the first gas inlet conduit 14, and thus connected with the first gas inlet conduit 14. In this embodiment, the first switching element 21 has mass flow controllers 211 and 213 which control the flow rates of the hydrogen gas and nitrogen gas as carrier gases accompanied with a group-V gas, respectively, and valves 212 and 214 provided between the mass flow controllers 211, 213 and the first gas inlet conduit 14. Moreover, the first switching element 21 has a valve 216 for a raw material gas such as a group-V gas which is supplied from another raw material source under the control of flow rate.

The second switching element 22 is an element for switching the gases to be supplied to the second gas inlet conduit 15, and thus connected with the second gas inlet conduit 15. In this embodiment, the second switching element 22 has mass flow controllers 221 and 223 which control the flow rates of the hydrogen gas and nitrogen gas as carrier gases accompanied with a group-V gas or subflow gases, respectively, and valves 222 and 224 provided between the mass flow controllers 221, 223 and the second gas inlet conduit 15. Moreover, the second switching element 22 has a valve 226 for a raw material gas such as a group-V gas which is supplied from another raw material source under the control of flow rate.

The third switching element 23 is an element for switching the gases to be supplied to the third gas inlet conduit 16, and thus connected with the third gas inlet conduit 16. In this embodiment, the third switching element 23 has mass flow controllers 231 and 233 which control the flow rates of the hydrogen gas and nitrogen gas as carrier gases accompanied with a group-III gas, respectively, and valves 232 and 234 provided between the mass flow controllers 231, 233 and the third gas inlet conduit 16. Moreover, the third switching element 23 has a valve 236 for a raw material gas such as a group-III gas which is supplied from another raw material source and which is accompanied with the carrier gas under the control of flow rate under the control of flow rate.

The fourth switching element 24 is an element for switching the gases to be supplied to the fourth gas inlet conduit 17, and thus connected with the fourth gas inlet conduit 17. In this embodiment, the fourth switching element 24 has mass flow controllers 241 and 243 which control the flow rates of the hydrogen gas and nitrogen gas as carrier gases accompanied with a group-III gas or subflow gases, respectively, and valves 242 and 244 provided between the mass flow controllers 241, 243 and the fourth gas inlet conduit 17. Moreover, the fourth switching element 24 has a valve 246 for a raw material gas such as a group-III gas which is supplied from another raw material source and which is accompanied with the carrier gas under the control of flow rate.

The fifth switching element 25 is an element for switching the gases to be supplied to the fifth gas inlet conduit 18, and thus connected with the fifth gas inlet conduit 18. In this embodiment, the fifth switching element 25 has mass flow controllers 251 and 253 which control the flow rates of the hydrogen gas and nitrogen gas as subflow gases, respectively, and valves 252 and 254 provided between the mass flow controllers 251, 253 and the fifth gas inlet conduit 18.

The sixth switching element 26 is an element for switching the gases to be supplied to the sixth gas inlet conduit 19, and thus connected with the sixth gas inlet conduit 19. In this embodiment, the sixth switching element 26 has mass flow controllers 261 and 263 which control the flow rates of the hydrogen gas and nitrogen gas as subflow gases, respectively, and valves 262 and 264 provided between the mass flow controllers 261, 263 and the sixth gas inlet conduit 19.

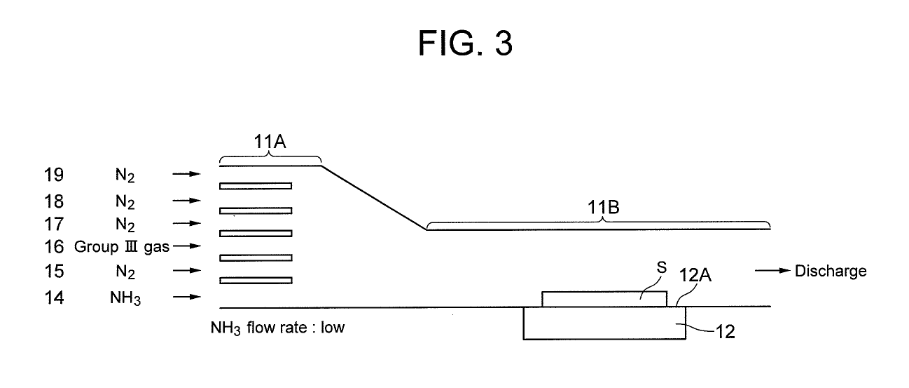

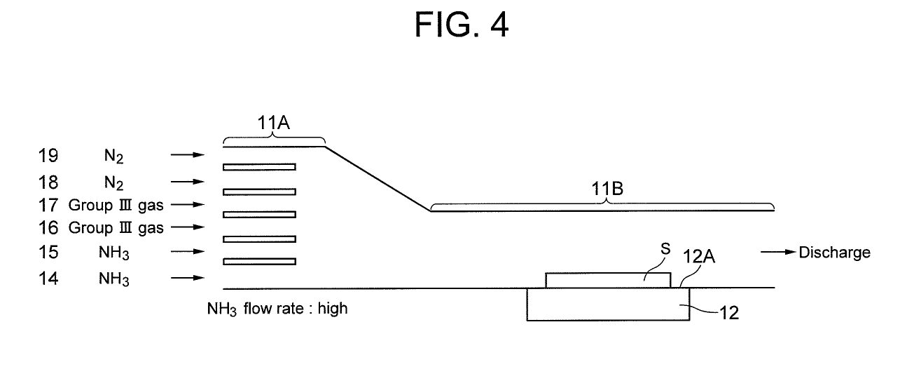

Then, the vapor-phase growing method using the vapor-phase growing apparatus will be described. FIGS. 3 and 4 are explanatory views relating to the vapor-phase growing method in this embodiment.

For clarifying the features of the vapor-phase growing apparatus 10 and the vapor-phase growing method as will be described below, in this embodiment, trimethyl gallium (TMG, Ga(CH₃)₃) is employed as a group-III gas and ammonia (NH₃) gas is employed as a group-V gas to form a GaN film on the substrate S. In this embodiment, moreover, the flow rate of the NH₃ gas is mainly changed remarkably for the aforementioned purpose.

In the case that a blue light emitting element is formed on a sapphire substrate, for example, it is required that some GaN layers such as a low temperature buffer GaN layer, a high temperature GaN layer, a Si-doped GaN layer, a barrier GaN layer for an active layer and a Mg-doped GaN layer are formed. In this case, the appropriate flow rate of the NH₃ gas may be different per GaN film.

In the case that the GaN film is formed using the TMG and NH₃ gas, as shown in FIGS. 3 and 4, the gas inlet portion relating to the TMG is set away from the substrate S relative to the gas inlet portion relating to the NH₃ gas. Moreover, the gas inlet portions relating to the subflow gas such as nitrogen gas is set away from the substrate S relative to the gas inlet portion relating to the TMG. In FIGS. 3 and 4, the group-III gas means the TMG and a carrier gas accompanied with the TMG. The NH₃ gas means only NH₃ gas or NH₃ gas accompanied with a carrier gas.

This arrangement of the gas inlet portions means that the partial pressure of the NH₃ gas can be set higher on the surface of the substrate S even in the case that all of the gases to be supplied are mixed because the gas inlet portion relating to the NH₃ gas is set in the vicinity of the substrate S. The crystallinity of the GaN film may be enhanced by setting the partial pressure of the NH₃ gas on the surface of the substrate S.

Moreover, if the TMG is supplied onto the high temperature portion in the upstream of the substrate S, the matters decomposed from the TMG and the GaN film are deposited on the upstream of the substrate S, causing the waste consumption of the TMG. In this embodiment, however, since the gas inlet portion relating to the TMG is set away from the substrate S relative to the gas inlet portion relating to the NH₃ gas, the TMG cannot be reached to the bottom wall surface of the reactor 11 if the TMG is not diffused in the flow of the NH₃ gas so that the consumption of the TMG at the high temperature portion in the upstream of the substrate S can be decreased.

Moreover, when the subflow gas is supplied to the gas inlet portion away from the substrate S relative to the gas inlet portion relating to the TMG, the TMG cannot be reached to the top wall surface of the reactor 11 if the TMG is not diffused in the flow of the subflow gas so that the consumption of the TMG at the top wall surface of the reactor 11 and the depositions on the top wall surface of the reactor 11 can be decreased. This effect/function becomes conspicuous when the flows of the gases to be used are not disturbed at the gas mixing portion. When the vortex flow occurs at the gas mixing portion, the NH₃ gas is mixed with another gas so that the partial pressure at the surface of the substrate S is decreased, for example. Moreover, since the TMG is likely to be reached to the wall surface of the reactor 11 through the mixture of the gases so that the partial pressure of the TMG is decreased and the diffusion of the TMG to the substrate S is also decreased.

If the depositions are formed on the wall surface of the reactor 11 as described above, the depositions are affected by the heating and cooling process through the continuous use of the reactor 11, that is, the vapor-phase growing apparatus 10 so as to be exfoliated and adhered with the film (GaN film in this embodiment) under or after formation, deteriorating the properties of the GaN film.

In this embodiment, therefore, the gas inlet portion relating to the TMG is set away from the substrate S relative to the gas inlet portion relating to the NH₃ gas and the gas inlet portion relating to the subflow gas such as the nitrogen gas is set away from the substrate S relative to the gas inlet portion relating to the TMG in order to avoid the aforementioned disadvantages.

In view of the aforementioned actual condition, in FIG. 3, the NH₃ gas is supplied to the gas introduction portion 11A of the reactor 11 from the first switching element 21 of the switching device 20 connected with the first gas inlet conduit 14 while the nitrogen gas as the subflow gas is supplied to the gas introduction portion 11A of the reactor 11 from the second switching element 22 of the switching device connected with the second gas inlet conduit 15.

Moreover, the TMG and the carrier gas accompanied therewith are supplied to the gas introduction portion 11A of the reactor 11 from the third switching element 23 of the switching device 20 connected with the third gas inlet conduit 16 while the nitrogen gas as the subflow gas is supplied to the gas introduction portion 11A of the reactor 11 from the fourth switching element 24 of the switching device 20 connected with the fourth gas inlet conduit 17.

Furthermore, the nitrogen gas as the subflow gas is supplied to the gas introduction portion 11A of the reactor 11 from the fifth switching element 25 of the switching device 20 connected with the fifth gas inlet conduit 18 while the nitrogen gas as the subflow gas is supplied to the gas introduction portion 11A of the reactor 11 from the sixth switching element 26 of the switching device 20 connected with the sixth gas inlet conduit 19.

In this case, the NH₃ gas is supplied to the gas inlet portion 11A of the reactor 11 at a predetermined flow rate via the first switching element 21 and the first gas inlet conduit 14 while the TMG and the carrier gas accompanied therewith are supplied to the gas introduction portion 11A of the reactor 11 via the third switching element 23 and the third gas inlet conduit 16. Moreover, the nitrogen gas as the subflow gas is introduced into the gas introduction portion 11A of the reactor 11 at a predetermined flow rate via the second switching element 22, the second gas inlet conduit 15, the fourth switching element 24, the fourth gas inlet conduit 17, the fifth switching element 25, the fifth gas inlet conduit 18, the sixth switching element 26 and the sixth gas inlet conduit 19.

In this embodiment, since the height “H1” of the gas introduction portion 11A of the reactor 11 is set larger than the height “h1” of the gas reaction portion 11B, the flow velocities of the NH₃ gas, the TMG, the carrier gas and the nitrogen gas which are introduced into the reactor 11 become low in the gas introduction portion 11A, respectively, so that their gases are flowed in the state of laminar flow at the gas introduction portion 11A. Thereafter, when the gases are flowed in the gas reaction portion 11B, the flow velocities of the gases become high due to the downsizing of the cross sectional area of flow path and the cubical expansion originated from the increase in temperature of the gases. Since the diffusion distance of the TMG to the substrate S becomes small by decreasing the cross sectional area of flow path, the TMG can be effectively and efficiently supplied to the substrate S. Since the gases are flowed in the state of laminar flow, the partial pressure of the NH₃ gas at the surface of the substrate S can be maintained high. Therefore, the GaN film is formed on the substrate S in a predetermined thickness. The substrate S may be rotated.

The NH₃ gas, the TMG gas, the carrier gas and the nitrogen gas are set to the respective predetermined flow velocities so that the flow of the gases is not disturbed originated from that the flow velocities of one or more of the gases become high.

Supposed that the flow rate of the NH₃ gas to be introduced is set more than that in the embodiment related to FIG. 3 in the formation of the GaN film on the substrate S. For example, if the flow rate of the NH₃ gas is set twice as high as that in the embodiment related to FIG. 3, the flow velocity of the NH₃ gas is required to be set twice as high in the case of the embodiment related to FIG. 3 via the first switching element 21 and the first gas inlet conduit 14.

In this case, since the flow velocity of the NH₃ gas becomes twice as high, the static pressure of the gas flow of the NH₃ gas relating to the equation (1) is decreased so that the TMG gas, the carrier gas and the subflow gas are attracted around the gas flow of the NH₃ gas. As a result, the vortex flow of the NH₃ gas, the TMG gas, the carrier gas and/or the subflow gas may occur in the reactor 11. In this case, the NH₃ gas is mixed with another gas so that the partial pressure of the NH₃ gas on the surface of the substrate S is decreased. Moreover, the TMG is mixed with another gas so as to be likely to be reached to the wall surface of the reactor 11. At the same time the partial pressure of the TMG is decreased so that the diffusion amount of the TMG to the surface of the substrate S is also decreased.

Moreover, the NH₃ gas, the TMG and/or the subflow gas may be reached to the top wall surface and the bottom wall surface of the reactor 11, particularly the gas reaction portion 11B with smaller height so as to form given depositions on the top wall surface and the bottom wall surface thereof by the disturbance of those gases. The depositions may be exfoliated during the use of the reactor 11, that is, the vapor-phase growing apparatus 10 and thus adhered with and deposited on the GaN film on the substrate S after or under formation, deteriorating the quality of the GaN film.

In the case that the flow rate of the NH₃ gas is set twice as high as described above, the NH₃ gas is also introduced into the gas introduction portion 11A of the reactor 11 from the second gas inlet conduit 15 by closing the valve 224 and opening the valve 226 of the second switching element 22 of the switching device 20 which is connected with the second gas inlet conduit 15 instead that the flow velocity of the NH₃ gas is set twice as high as described above.

In this case, as shown in FIG. 4, the NH₃ gas is introduced into the gas introduction portion 11A of the reactor 11 via the first switching element 21, the first gas inlet conduit 14, the second switching element 22 and the second gas inlet conduit 15. Namely, the NH₃ gas is introduced via two switching elements and two gas inlet conduits instead of one switching element and one gas inlet conduit in the embodiment related to FIG. 3.

Therefore, even though the flow rate of the NH₃ gas is set twice as high, the NH₃ gas can be introduced under the condition that the flow velocity of the NH₃ from each of the switching elements and each of the gas inlet conduits can be maintained in the same manner in the embodiment related to FIG. 3. In this point of view, the change of the static pressure around the gas flow of the NH₃ gas can be reduced so that the vortex of the TMG, the carrier gas and the subflow gas can be suppressed around the gas flow of the NH₃ gas.

As a result, the partial pressure of the NH₃ gas on the surface of the substrate S can be set higher to form the GaN film with good crystallinity under the condition that the vortex flow of the NH₃ gas, the TMG, the carrier gas and/or the subflow gas does not occur. Moreover, the waste consumption of the TMG gas and the reduction of the partial pressure of the TMG can be suppressed.

Furthermore, the formation of the depositions on the top wall surface and the bottom wall surface of the reactor 11, particularly the gas reaction portion 11B with smaller height, which is originated from that the NH₃ gas, the TMG, the carrier gas and/or subflow gas are reached to the top wall surface and the bottom wall surface thereof, can be reduced, suppressing the deterioration in quality of the GaN film formed on the substrate S.

In the above case, the flow rate of the NH₃ gas is set twice as high, but if the flow rate of the NH₃ gas is set three time as high, the raw material gases such as the NH₃ gas and the TMG and the subflow gas can be uniformly supplied onto the substrate S under no disturbance of the gas flow of those gases in the same manner as the embodiment related to FIG. 4 using the NH₃ gas at the fifth switching element 25 of the switching device 20 instead of the nitrogen gas and the hydrogen gas as the subflow gas thereat, thereby enhancing the reproducibility of the formation of the GaN film.

In the case that the flow rates of the TMG and the carrier gas are much more than those in the embodiment related to FIG. 3 in the formation of the GaN film on the substrate S, if the flow rates of the TMG and the carrier gas are set twice as high as those in the embodiment related to FIG. 3, for example, the flow rates of the TMG and the carrier gas can be set in the same manner as the case relating to the NH₃ gas.

In this case, the TMG and the carrier gas are also introduced into the gas introduction portion 11A of the reactor 11 from the fourth gas inlet conduit 17 by opening the valve 246 of the fourth switching element 24 of the switching device 20.

Therefore, the TMG is introduced into the gas introduction portion 11A of the reactor 11 via the third switching element 23, the third gas inlet conduit 16, the fourth switching element 24, the fourth gas inlet conduit 24. Namely, the TMG and the carrier gas accompanied therewith are introduced via two switching elements and two gas inlet conduits instead of one switching element and one gas inlet conduit in the embodiment related to FIG. 3.

Therefore, even though the flow rates of the TMG and the carrier gas are set twice as high, the TMG and the carrier gas can be introduced under the condition that the flow velocities of the TMG and the carrier gas from each of the switching elements and each of the gas inlet conduits can be maintained in the same manner in the embodiment related to FIG. 3. In this point of view, the reduction of the static pressure around the gas flows of the TMG and the carrier gas can be suppressed so that the NH₃ gas and the subflow gas are not attracted around the gas flows of those gases.

As a result, the vortex of the NH₃ gas, the TMG, and/or the subflow gas can be suppressed so that the NH₃ gas, the TMG and/or the subflow gas can be supplied onto the substrate S disposed in the gas reaction portion 11B of the reactor 11 under good repeatability, thereby enhancing the reproducibility of the GaN film to be formed.

Moreover, the formation of the depositions on the top wall surface and the bottom wall surface of the gas reaction portion 11B with smaller height can be reduced, suppressing the deterioration in quality of the GaN film due to the exfoliation of the depositions.

As shown in FIG. 2 furthermore, the first switching element 21 through the six switching element 26 are configured so as to introduce the hydrogen gas as the subflow gas or the carrier gas instead of the nitrogen gas by switching the valves 212, 214 and the like. Such switching may cause the reduction of the gas density ρ so as to suppress the decrease of the static pressure as indicated in Equation (1) and enhance the diffusion coefficient of the TMG in the vapor-phase and thus diffusion velocity of the TMG to the substrate S. In order to enhance the flatness of the GaN film, the mixed gas of the nitrogen gas and the hydrogen gas may be employed via a mass flow controller.

In the aforementioned embodiments, the TMG is employed as the group-III gas and the NH₃ gas is employed as the group-V gas. As the group-III gas can be exemplified trimethyl indium (TMI, In(CH₃)₃) and trimethyl aluminum (TMA, Al(CH₃)₃) in addition to the TMG. As the group-V gas can be exemplified tert-butyl amine (t-C₄H₉NH₂), monomethyl hydrazine (N₂H₃ (CH₃)), arsine (AsH₃), phosphine (PH₃) in addition to the NH₃. Then, as an n-type dopant can be used silane (SiH₄) and as a p-type dopant can be used dicyclopentadienyl magnesium ((C₅H₅)₂Mg) can be used.

In the case of the growth of an InGaN layer, TMG and TMI are employed as the group-III gas. In the case of the growth of an AlGaN layer, TMG and TMA are employed. In the case of the growth of a GaAs layer, AsH₃ is employed as the group-V gas.

In addition to the aforementioned group-III gas and group-V gas, group-II gas such as dimethyl zinc (Zn(CH₃)₂), group-IV gas such as methane (CH₄) and group-VI gas such as hydrogen selenide (H₂Se) may be employed.

In the growth of a ZnSe layer, Zn(CH₃)₂ and H₂Se are employed. In the growth of a carbon film, CH₄ is employed.

In addition to the nitrogen gas and the hydrogen gas, argon gas may be employed as the subflow gas.

In the aforementioned embodiments, the flow rate of the NH₃ gas is changed to form the same GaN film, but may be changed to form a film with a different composition such as an InGaN film. Moreover, the degree in change of the flow rate of the gas is not limited to be twice as high, but may be set to any times as high only if the kinds and flow rates of the gases to be employed are appropriately selected so as not to cause the disturbance of gas flow at the gas mixing portion.

### Second Embodiment

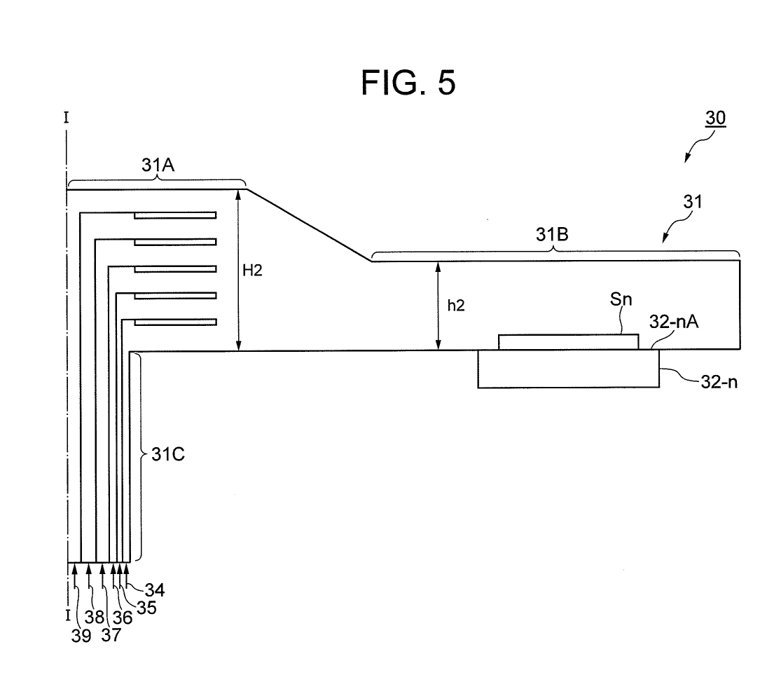

FIG. 5 is a cross sectional view schematically showing the structure of a vapor-phase growing apparatus according to a second embodiment. As shown in FIG. 5, a vapor-phase growing apparatus 30 in this embodiment includes a so-called pancake or planetary reactor 31 containing a gas introduction portion 31A and a gas reaction portion 31B continued from the gas introduction portion 31A and susceptors 32-n which are arranged concentrically around the center axis I-I of the pancake or planetary reactor 31 and of which the respective surfaces are exposed to the interior space of the gas reaction portion 31B of the reactor 31. Then, substrates Sn are disposed on the corresponding susceptors 32-n, respectively. The susceptors 32-n are held on a not-shown table and the table and the susceptors 32-n are heated to keep the substrate at a prescribed temperature. In the case that the vapor-phase growing apparatus is configured as a rotation/revolution type apparatus, the table (not shown) is revolved while the susceptors 32-n are rotated, which does not matter.

Since the reactor 31 of the vapor-phase growing apparatus 30 is configured as the pancake or planetary apparatus, the substrates Sn are arranged circularly along the periphery of the reactor 31 which is not particularly illustrated. The symbol “n” means the number of substrate to be arranged while the symbol “32-n” means the number of susceptor by adding the sub number “n” to the base number “32” for distinguishing the susceptors from one another because the number of susceptor is required to be set equal to the number of substrate.

In the vapor-phase growing apparatus 30 of the present embodiment, since the reactor 31 is configured as the pancake or planetary reactor, the reactor 31 contains, at the center thereof, a gas introduction-elongated portion 31C which is projected downward from the gas introduction portion 31A so that raw material gases and a subflow gas are introduced into the gas introduction portion 31A via a first gas inlet conduit 34 through a sixth gas inlet conduit 39 provided in the gas introduction-elongated portion 31C. The first gas inlet conduit 34 through the sixth gas inlet conduit 39 are provided and arranged in the gas introduction-elongated portion 31C so as to supply the corresponding gases subsequently from the side near the substrates Sn to the side away from the substrates Sn.

Moreover, since the reactor 31 is configured as the pancake or planetary reactor, explanation is imparted to the right side cross section of the reactor 31 relative to the center axis “I-I” in order to clarify the features of the vapor-phase growing apparatus and the vapor-phase growing method, but may be imparted to all of the cross sections of the reactor 31 because the reactor 31 is configured axial symmetry relative to the center axis “I-I” of the reactor 31.

In the reactor 31, the height “H2” of the gas introduction portion 31A is set equal to the height “h2” of the gas reaction portion 31B, but desirably, the height “H2” of the gas introduction portion 31A is set larger than the height “h2” of the gas reaction portion 315. The ratio (H2/h2) of the height “H2” of the gas introduction portion 31A to the height “h2” of the gas reaction portion 31B is set within a range of 1 to 5. However, the concrete height “H2” and the concrete height “h2” are determined in view of the size of the substrate S, the flow rates of the gases to be used at the film-forming processes for the substrate S, the growing pressure and the like.

Since the radius of the gas introduction portion 31A of the pancake or planetary reactor 31 is smaller than the radius at the area where the substrates Sn are arranged, the cross section of flow path at the gas introduction portion 31A becomes smaller than the cross section of flow path at the area where the substrates Sn are arranged so that the flow velocity “u” becomes higher at the gas introduction portion 31A. Therefore, the degree in decrease of the static pressure “p” in Equation (1) becomes larger than that in the lateral reactor related to the first embodiment. In this point of view, the effect/function of increasing the height of the gas introduction portion 31A so as to reduce the flow velocity “u” and suppressing the unbalance of the static pressure at the gas mixing portion is much enhanced in the pancake or planetary reactor in comparison with the lateral reactor.

In the vapor-phase growing apparatus 30 in this embodiment, a switching device 20 for switching the gases to be supplied to the gas inlet conduits 34 to 39 is provided in the outside of the reactor 31. As described in the first embodiment, therefore, if the flow rate of the NH₃ gas is set twice as high, instead of setting the flow velocity of the NH₃ gas twice as high, the NH₃ gas is introduced into the gas introduction portion 11A of the reactor 11 from the second gas inlet conduit 35 by closing the valve 224 and opening the valve 226 in the second switching element 22 of the switching device 20 which is connected with the second gas inlet conduit 35.

In this case, the NH₃ gas is introduced into the gas introduction portion 31A of the reactor 31 via the first switching element 21, the first gas inlet conduit 34, the second switching element 22 and the second gas inlet conduit 35. Namely, the NH₃ gas is introduced via two switching elements and two gas inlet conduits.

Therefore, even though the flow rate of the NH₃ gas is set twice as high, the NH₃ gas can be introduced under the condition that the flow velocity of the NH₃ from each of the switching elements and each of the gas inlet conduits can be maintained. In this point of view, the change of the static pressure around the gas flow of the NH₃ gas can be reduced so that the vortex of the TMG and the subflow gas can be suppressed around the gas flow of the NH₃ gas.

As a result, in the reactor 31, the partial pressure of the NH₃ gas on the surfaces of the substrate Sn can be set higher to form the GaN film with good crystallinity under the condition that the vortex flow of the NH₃ gas, the TMG, the carrier gas and/or the subflow gas does not occur. Moreover, the waste consumption of the TMG gas and the reduction of the partial pressure of the TMG can be suppressed.

Furthermore, the formation of the depositions on the top wall surface and the bottom wall surface of the reactor 31, particularly the gas reaction portion 31B with smaller height can be reduced, suppressing the deterioration in quality of the GaN film formed on the substrate Sn.

The flow rate of the TMG can be controlled in the same manner as in the first embodiment. Other features and advantages are similar to those in the first embodiment and thus omitted in this embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A vapor-phase growing apparatus, comprising:
a reactor containing a gas introduction portion and a gas reaction portion continued from the gas introduction portion;
a susceptor, of which a surface is exposed in an interior space of the gas reaction portion of the reactor, for disposing and fixing a substrate on the surface thereof;
a plurality of gas inlet conduits which are arranged subsequently along a direction of height of the reactor in the gas introduction portion of the reactor; and
a switching device, which is provided in an outside of the reactor, for switching gases to be supplied to the gas inlet conduits, respectively.

2. The apparatus as set forth in claim 1,
wherein the switching device is configured so as to switch a raw material gas, a carrier gas and a subflow gas to be supplied to the gas inlet conduits, respectively and control a flow rate of the raw material gas to be supplied to the gas inlet conduits.

3. The apparatus as set forth in claim 1,
wherein a height of the gas introduction portion of the reactor is set larger than a height of the gas reaction portion of the reactor.

4. The apparatus as set forth in claim 1,
wherein the raw material gas is at least one selected from the group consisting of group-II gas, group-III gas, group-IV gas, group-V gas and group-VI gas.

5. The apparatus as set forth in claim 4,
wherein the raw material gas contains a first raw material gas of the group-III gas and a second raw material gas of the group-V gas, and
wherein the corresponding one of the gas inlet conduits relating to the first raw material gas is set away from the substrate relative to the corresponding one of the gas inlet conduits relating to the second raw material gas.

6. The apparatus as set forth in claim 5,
wherein the corresponding one of the gas inlet conduits relating to the subflow gas is set away from the substrate relative to the corresponding one of the first raw material gas.

7. The apparatus as set forth in claim 1,
wherein the subflow gas and the carrier gas are at least one selected from the group consisting of nitrogen gas, hydrogen gas and argon gas.

8. The apparatus as set forth in claim 1,
wherein the reactor is configured as a lateral reactor, a pancake reactor or a planetary reactor.

9. A vapor-phase growing method, comprising:
disposing and fixing a substrate on a susceptor, in a reactor containing a gas introduction portion and a gas reaction portion continued from the gas introduction portion, of which a surface is exposed in an interior space of the gas reaction portion of the reactor;
supplying a raw material gas, a carrier gas and a subflow gas to the gas introduction portion of the reactor from a plurality of gas inlet conduits which are arranged subsequently along a direction of height of the reactor in the gas introduction portion of the reactor to form a first film on the substrate; and
switching the raw material gas, the carrier gas and the subflow gas by a switching device, which is provided in an outside of the reactor, for switching gases to be supplied to the gas inlet conduits, respectively so as to control a flow rate of the raw material gas to be supplied to the gas inlet conduits of the reactor to form a second film on the first film.

10. The method as set forth in claim 9,
wherein a height of the gas introduction portion of the reactor is set larger than a height of the gas reaction portion of the reactor.

11. The method as set forth in claim 9,
wherein the raw material gas is at least one selected from the group consisting of group-II gas, group-III gas, group-IV gas, group-V gas and group-VI gas.

12. The method as set forth in claim 11,
wherein the raw material gas contains a first raw material gas of the group-III gas and a second raw material gas of the group-V gas, and
wherein the corresponding one of the gas inlet conduits relating to the first raw material gas is set away from the substrate relative to the corresponding one of the gas inlet conduits relating to the second raw material gas.

13. The method as set forth in claim 12,
wherein the corresponding one of the gas inlet conduits relating to the subflow gas is set away from the substrate relative to the corresponding one of the first raw material gas.

14. The method as set forth in claim 9,
wherein the subflow gas and the carrier gas are at least one selected from the group consisting of nitrogen gas, hydrogen gas and argon gas.

15. The method as set forth in claim 9,
wherein the reactor is configured as a lateral reactor, a pancake reactor or a planetary reactor.
